(19) United States
(12) Patent Application Publication
(10) Pub. No.: US 2008/0203538 A1
(43) Pub. Date: Aug. 28, 2008

(54) Semiconductor wafer with division guide pattern

(75) Inventors: Takahiro Kumakawa, Souraku-gun (JP); Masaki Utsumi, Uji-shi (JP); Yoshihiro Matsushima, Kyoto-shi (JP); Masami Matsuura, Nagaokakyo-shi (JP)

Correspondence Address: STEPTOE & JOHNSON LLP, 1330 CONNECTICUT AVENUE, N.W., WASHINGTON, DC, 20036, US

(73) Assignee: Matsushita Electric Industrial Co., Ltd., Kadoma-shi (JP)

(21) Appl. No.: 12/149,148

(22) Filed: Apr. 28, 2008

Related U.S. Application Data
(62) Division of application No. 11/288,378, filed on Nov. 29, 2005.

(30) Foreign Application Priority Data
Jan. 21, 2005 (JP) 2005-013448

(51) Int. Cl. H01L 23/00; H01L 21/78

(52) U.S. Cl. 257/620; 438/114; 257/E21.599; 257/E21.347; 257/E23.002

(57) ABSTRACT

A plurality of semiconductor elements and division regions are provided on a semiconductor subsubstrate. A modification region is provided in the semiconductor substrate. A division guide pattern is provided at least in a portion of each division region. A cleavage produced from a starting point corresponding to the modification region is guided by the division guide pattern.

### FIELD OF THE INVENTION

The present invention generally relates to dicing for dividing a semiconductor wafer into individual semiconductor devices (chips). The present invention makes it possible to reduce the width of a dicing lane which is a region necessary for dividing with substantially no chipping in dicing, and provides a technique relating to a semiconductor wafer structure optimized for working on a semiconductor wafer by laser working.

### BACKGROUND OF THE INVENTION

Blade dicing techniques have been used most generally in semiconductor wafer dicing processes. In a blade dicing technique, a semiconductor wafer is worked in a fracturing working manner in a dicing lane by an annular dicing saw rotating at a high speed.

The dicing lane is a region necessary for dividing and corresponds to an actual dicing width determined by dicing with the dicing saw. On the dicing saw, a powder of diamond or cubic boron nitride (CBN) is retained by a bonding material.

In such working techniques for dicing a semiconductor wafer with a dicing saw, work qualities have been improved by modifying the specifications of the dicing saw (for example, with respect to the grain size of the particle size and density of diamond particles, and a bonding material) and working conditions including the rotational speed of the dicing saw, the feed speed and the cutting depth and optimizing the specifications and the conditions.

However, there is a limit to the improvements in work qualities achieved by optimizing the conditions of working with a dicing saw. In the case of fracture working using a dicing saw, a further improvement in work qualities cannot be expected with respect to problems described below in particular.

(1) Chipping occurs in a cut surface of a semiconductor substrate at the time of fracture working, resulting in a reduction in mechanical strength of the semiconductor substrate after dicing.

(2) Chips formed by chipping act as dust to affect yield in steps after dicing or the reliability of the product.

(3) There is a need to set the width of each scribe area (called a scribe lane) on scribe lines (scribe grid) wider than the width of dicing lanes, i.e., the actual dicing width of dicing with a dicing saw, in order to avoid chipping in the regions of semiconductor devices on a semiconductor wafer.

(4) In ordinary cases, it is necessary to set the thickness of a dicing saw to 20 μm or more in order to maintain the desired mechanical strength of the saw.

(5) In recent years, semiconductor process rules (process sizes) have become finer and a low-k material (low dielectric interlayer insulating film material) has been used as interlayer insulating film. However, low-k materials are ordinarily brittle and have low adhesion. Therefore, interlayer film separation of a low-k material can occur easily by damage to the material during dicing.

In recent years, working methods using laser light have attracted attention as a method for solving the above-described problems. As this kind of working method, a working method described in Japanese Patent Laid-Open No. 2002-19237 for example is known.

In this method, a modification region is formed in an object by multi-photon absorption. Multi-photon absorption is a phenomenon in which if the intensity of light is increased to a very high level, absorption in a material occurs even when the energy of the photons is smaller than a band gap of the material, that is, the material is optically transparent.

This laser working method will be described with reference to drawings. FIG. 8 is a plan view of a semiconductor wafer, showing a scribe line (scribe area) on a semiconductor wafer to be worked. FIGS. 9A and 9B are sectional views during laser working taken along line b-b′ in FIG. 8.

In FIGS. 8, 9A, and 9B, reference numeral 101 denotes a semiconductor wafer; reference numeral 102 a scribe lane; reference numeral 102a a center of the scribe lane; reference numeral 103 laser light; reference numeral 104 a modification region; and reference numeral 105 a cut (crack) produced from a starting point corresponding to the modification region 104.

First, under a condition for causing multi-photon absorption, laser light 103 is radiated by adjusting a focal point in the semiconductor wafer 101. The focal point of laser light 103 is moved for scanning along the center (dicing lane) 102a of the scribed lane 102 while continuously or intermittently causing multi-photon absorption. By this scanning with laser light 103, the modification region 104 is formed in the semiconductor wafer 101 along the scribe lane 102.

A cleavage is produced from a starting point corresponding to the modification region 104. A cut (crack) 105 is formed by this cleavage to crack the semiconductor wafer 101 along the dicing lane, thus performing dicing.

Thus, dicing of the semiconductor wafer can be performed without producing an unnecessary crack deviating from the dicing lane, i.e., chipping. Also, the semiconductor wafer 101 can be easily divided by a comparatively small external force. In particular, if the semiconductor wafer 101 is thin, it can crack spontaneously in the direction of thickness without receiving any substantial external force. If the semiconductor wafer 101 is thick, modification regions 104 maybe formed in a plurality of places in the thickness direction in parallel with each other. In this way, the semiconductor wafer can be easily divided.

As a result, the reduction in mechanical strength and the generation of dust due to chipping can be reduced. Also, the scribe area can be made extremely narrow since this dicing requires no cutting width in the planar direction of the semiconductor wafer 101 the dicing width (dicing lane) in contrast to fracture working.

The above-described conventional art, however, entail problems described below.

(1) Recent semiconductor manufacturing processes include a flattening process using chemical mechanical polishing (CMP).

Therefore an interlayer insulating film is also formed basically in the scribe lane region. In the case of lamination of a low-k material or the like, however, the adhesion between layers is considerably low and interface separation of interlayer insulating film is caused by damage at the time of cutting (cleavage) from a starting point corresponding to the modification region.

(2) When cutting is performed from a starting point corresponding the modification region, the linearity of the cleavage produced starting from the modification region is impaired if the distance between the modification region and the surface of the semiconductor wafer is increased. Thus, the linearity of cleavage produced in the surface of the semiconductor wafer is degraded.

An object of the present invention is to provide a semiconductor wafer on which surface layers such as interlayer insulating films and passivation films formed of a material different from the material of a semiconductor substrate are formed, and which, when being cut from a starting point corresponding to a modification region, can be divided so that the linearity of a cut portion is high, without causing interface separation between the interlayer insulating films and other films.

### DISCLOSURE OF THE INVENTION

To achieve the above-described object, according to the present invention, there is provided a semiconductor wafer having a lamination which is formed on a semiconductor substrate and in which a plurality of semiconductor elements and division regions for separating the plurality of semiconductor elements into individual semiconductor devices are provided, the semiconductor wafer including a modification region from which formation of a cleavage starts, the modification region being provided in the semiconductor substrate, and a division guide pattern for guiding the progress of the cleavage, the division guide pattern being formed at least in a portion of each division region.

The division guide pattern may be formed through the lamination in the lamination direction.

The division guide pattern may be formed in a continuous line configuration.

The division guide pattern may be formed of a group of a plurality of discontinuous pattern portions in a band configuration.

The division guide pattern is a combination of a division guide pattern in a continuous line configuration and a group of a plurality of discontinuous pattern portions in a band configuration.

The division guide pattern may include a slit formed in the lamination.

The division guide pattern may include a metal layer pattern in the lamination including interlayer insulating film and passivation film.

The metal layer pattern may have a stack structure in which vias and wiring layers are stacked.

The metal layer pattern may be in a dot form.

The width of the division region in which the division guide pattern is formed may be set to 30 μm or less.

According to the present invention, there is also provided a method of manufacturing a semiconductor device, including forming a semiconductor wafer by forming a lamination on a semiconductor substrate, and performing scanning with laser light, wherein when the semiconductor wafer is formed, a plurality of semiconductor elements, division regions for separating the plurality of semiconductor elements into individual semiconductor devices and a division guide pattern formed at least in a portion of each division region are provided in the lamination, and wherein when scanning with laser light is performed, laser light is moved for scanning along the division guide pattern formed in each division region in the semiconductor wafer; a modification region is formed in the semiconductor substrate by irradiation with the laser light; and a cleavage produced from a starting point corresponding to the modification region is guided by the division guide pattern.

The method may also include dividing the semiconductor wafer. When the semiconductor wafer is divided, a mechanical stress is produced in the semiconductor wafer along the division guide pattern; the cleavage produced from a starting point corresponding to the modification region in the semiconductor substrate is guided by the division guide pattern; and the semiconductor wafer is divided along the division guide patterns to be separated into the individual semiconductor devices.

When scanning with the laser light is performed, the laser light may be radiated while adjusting a focal point to an internal portion of the semiconductor substrate to form the modification region in the semiconductor substrate by multi-photon absorption.

The above-described scanning with the laser light may be performed a certain number of times by changing the focal point. When scanning with the laser light is performed, the modification region may be formed adjacent to the division guide pattern.

According to the present invention, there is further provided a semiconductor device comprising a semiconductor element and a division guide pattern in a lamination formed on a semiconductor substrate, wherein a modification region formed in the semiconductor substrate and a cleavage surface extending from the modification region to the division guide pattern exist in a division surface along the division guide pattern forming a side surface of the semiconductor device.

According to the present invention, a cleavage is produced from a starting point corresponding to the modification region formed in the semiconductor substrate when the semiconductor wafer is divided by expansion or the like. This cleavage progresses in the direction of thickness of the semiconductor substrate and progresses toward the division guide pattern formed in the lamination. Therefore, unnecessary meandering is not caused in the cut portion (crack).

The formation of the division guide pattern through the lamination in the lamination direction enables the cleavage produced from a starting point corresponding to the modification region to progress along the division guide pattern in the lamination direction of the lamination to divide the lamination. There is, therefore, substantially no risk of interface separation in the lamination.

The formation of the division guide pattern in a continuous line configuration enables the cleavage produced from a starting point corresponding to the modification region to progress toward the division guide pattern in the direction of thickness of the semiconductor substrate and progress along the division guide pattern formed in a line configuration to divide the lamination, thus enabling a division surface having improved linearity to be obtained.

The formation of the division guide pattern by a group of a plurality of discontinuous pattern portions in band form enables the cleavage produced from a starting point corresponding to the modification region to progress toward the division guide pattern in the direction of thickness of the semiconductor substrate. At this time, even if meandering is abruptly caused due to an error factor, the division line (dicing lane) is defined within the division guide pattern in band form since the division guide pattern is in band form and has a predetermined width. That is, a margin is provided with respect to meandering. Therefore the guidance of the cleavage by the division guide pattern can be effectively executed.

A combination of the division guide pattern in a continuous line configuration and the group of discontinuous pattern portions in band form ensures that the desired linearity based on the division guide pattern formed in line form can be achieved while maintaining the desired margin with respect to abrupt meandering by means of the division guide pattern form in band form.

The division guide pattern is formed, for example, by a slit, a metal layer pattern and vias. Therefore there is no need to use any special process step for making the division guide pattern. The division guide pattern can be formed in an ordinary semiconductor wafer process.

The metal layer pattern has a stack structure in which vias and wiring layers are stacked. The interlayer insulating films are thereby anchored in the lamination, thus improving the adhesion between the interlayer insulating films. In this way, the effect of suppressing interface separation at the time of division of the semiconductor wafer is obtained. Also, the divisibility can be improved by promoting propagation in the stack direction of energy for dividing the semiconductor wafer.

The metal layer pattern is provided in a dot configuration to increase the area of contact between the metal layer pattern and the interlayer insulating films covering the metal layer pattern. The adhesion at the interface is thereby improved to suppress interface separation at the time of division of the semiconductor wafer.

According to the present invention, unnecessary meandering of the cleavage is not caused when the semiconductor wafer is divided. Therefore the width of the division regions can be set to 30 μm or less. Therefore the area occupied by the division regions which are essentially unnecessary regions in the semiconductor wafer can be effectively reduced.

According to the semiconductor device manufacturing method of the present invention, scanning with laser light is performed along the division guide pattern. Therefore the laser light working point (modification region) and the division guide pattern can be formed so as to superposed in the lamination direction of the lamination.

An effect described below is thereby obtained. When the semiconductor wafer is divided, the cleavage produced from a starting point corresponding to the modification region can easily progress toward the division guide pattern and does not meander by deviating the division guide pattern.

In the process of dividing the semiconductor wafer, a mechanical stress is produced in the semiconductor wafer along the division guide pattern. The mechanical stress produced in the semiconductor wafer acts on the modification region to cause the cleavage to progress from the modification region to the division guide pattern, thus enabling the semiconductor wafer to be easily divided.

In the process of scanning with laser light, the modification region is formed in the semiconductor substrate by adjusting the focal point in the semiconductor substrate, thus preventing scattering of a molten material at the time of laser working.

In the process of scanning with laser light, scanning is performed a certain number of times by changing the focal point. A plurality of modification regions are thereby formed in the semiconductor substrate at different depths to enable the semiconductor wafer to be easily divided even if the thickness of the semiconductor wafer is large.

In the process of scanning with laser light, the modification region is formed adjacent to the division guide pattern to enable the cleavage to positively progress along the division guide pattern, thus ensuring advantageously high cut surface quality.

In the semiconductor device in accordance with the present invention, a side surface of the semiconductor has the modification region formed in the semiconductor substrate and a cleavage surface extending from the modification region to the division guide pattern. The side surface is therefore formed as a division surface extending orderly along the division guide pattern. Thus, the semiconductor device has an extremely small amount of chipping, improved mechanical strength and high size accuracy in comparison with a semiconductor device having a surface formed by the fracture working using the conventional dicing saw.

### BRIEF DESCRIPTION OF THE DRAWINGS

FIG. 1 is a plan view of a semiconductor wafer according to the first to fourth embodiments of the present invention, showing scribe lanes provided as division regions and a peripheral region around the area containing the scribe lanes;

FIG. 2 is a sectional view of the semiconductor wafer according to the first embodiment of the invention;

FIGS. 3A to 3E are schematic diagrams showing a method of manufacturing a semiconductor device by using the semiconductor wafer according to the first embodiment of the present invention;

FIG. 4 is a sectional view of the semiconductor wafer according to the second embodiment of the present invention;

FIGS. 5A to 5G are sectional views showing a dividing method using the semiconductor wafer according to the second embodiment of the present invention;

FIG. 6 is a sectional view of the semiconductor wafer according to the third embodiment of the present invention;

FIG. 7 is a sectional view of the semiconductor wafer according to the fourth embodiment of the present invention;

FIG. 8 is a plan view showing scribe lanes and peripheral regions thereof in a semiconductor wafer which is an object to be worked by laser working, according to a conventional method of dicing a semiconductor substrate; and

FIGS. 9A and 9B are sectional views showing the conventional method of dicing a semiconductor substrate.

### DESCRIPTION OF THE EMBODIMENTS

Embodiments of a semiconductor wafer in accordance with the present invention will be described with reference to the accompanying drawings.

### First Embodiment

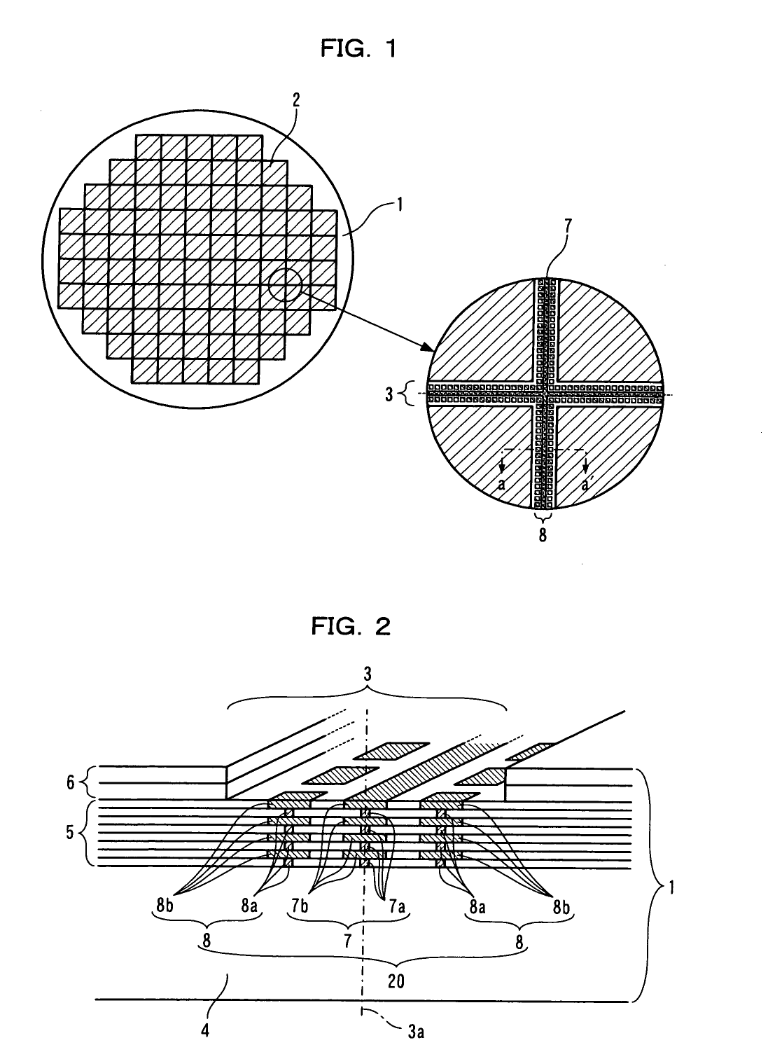

FIG. 1 is a plan view of a semiconductor wafer, showing scribe lanes provided as division regions and a peripheral region around the area containing the scribe lanes. FIG. 2 is a sectional view taken along line a-a′ in FIG. 1.

In FIGS. 1 and 2, reference numeral 1 denotes the semiconductor wafer; reference numeral 2 a semiconductor device (a semiconductor element); reference numeral 3 scribe lanes (division regions); reference numeral 4 a semiconductor substrate made essentially of silicon; reference numeral 5 interlayer insulating films typified by film of silicon oxide or organic glass; reference numeral 6 passivation films formed of silicon nitride or polyimide; reference numeral 7 a division guide line pattern; and reference numeral 8 division guide band patterns.

As shown in FIG. 1, a plurality of semiconductor devices 2 and scribe lanes 3 are formed on a lamination on the semiconductor substrate 4 of the semiconductor wafer 1. The plurality of semiconductor devices 2 are separated from each other by the scribe lanes 3. The scribe lanes 3 are division regions where the semiconductor wafer 1 is cut to be divided into the individual semiconductor devices 2.

As shown in FIG. 2, a division guide pattern 20 is formed in each scribe lane 3 through the lamination in the lamination direction. The division guide pattern 20 is formed of a combination of the division guide line pattern 7 and the division guide band patterns 8. The division guide band patterns 8 are formed on opposite sides of the division guide line pattern 7 in a band configuration.

The division guide line pattern 7 has a continuous linear configuration and has a metal layer pattern in the lamination of the interlayer insulating films 5. The metal layer pattern is formed through and across the interlayer insulating films 5 and has a stack structure in which line vias 7a and wiring pattern portions 7b formed of wiring layers are stacked. Each of the line vias 7a and the wiring pattern portions 7b has a shape continuous along the division guide line pattern 7.

For the line vias 7a, tungsten, copper, aluminum or polysilicon, for example, is used. For the wiring patterns 7b, aluminum or copper, for example, is used.

Each of the division guide band patterns 8 is formed of a group of a plurality of discontinuous pattern portions. Each pattern portion has a metal layer pattern in the lamination of the interlayer insulating films 5. The metal layer pattern is formed through the interlayer insulating films 5 and has a stack structure in which vias 8a and dot pattern portions 8b formed of wiring layers are stacked. Each of the vias 8a and the dot pattern portions 8b has a shape such that the vias 8a and the dot pattern portions 8b are discontinuous at positions between the pattern portions of the division guide band pattern 8.

The same material as that of the line vias 7a is used as the material of the vias 8a, and the same material as that of the dot pattern portions 8b is used as the material of the wiring pattern portions 7b.

Passivation films 6 are formed as uppermost layers on the semiconductor wafer 1. An opening in the form of a slit is formed in the passivation films 6 in correspondence with the scribe lane 3 region including the upper surface of the division guide pattern 20.

The opening in the passivation films 6 is formed through the entire width of the scribe lane 3. However, there is no problem even if the opening is formed only at a position corresponding to the division guide line pattern 7.

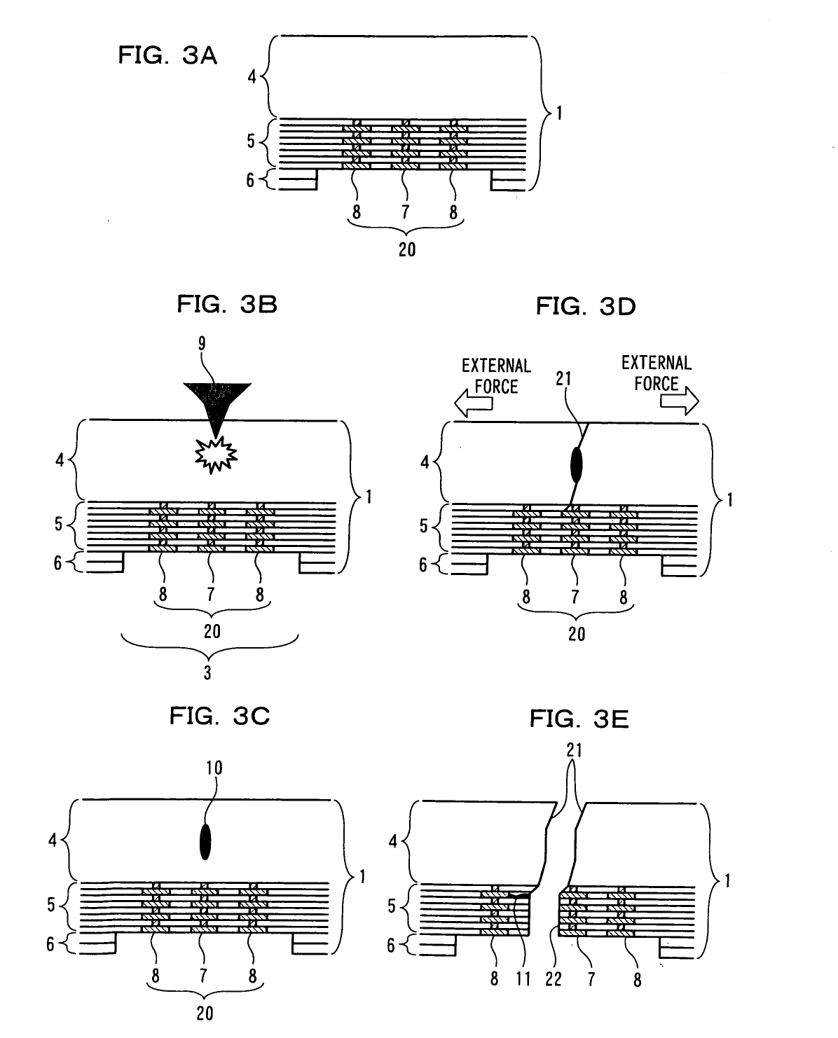

A method of manufacturing the semiconductor device by using the semiconductor wafer in accordance with the present invention will be described with reference to FIGS. 3A to 3E, which are schematic diagrams showing the method of manufacturing the semiconductor device by using the semiconductor wafer 1 shown in FIG. 2.

In FIGS. 3A to 3E, reference numeral 9 denotes laser light; reference numeral 10 a modification region worked with laser light is performed; and reference numeral 11 denotes interface separation caused between interlayer insulating films 5 at the time of dividing. Other portions are the same as those shown in FIGS. 1 and 2 and the description for them will not be repeated.

First, as shown in FIG. 3B, the semiconductor wafer 1 is irradiated with laser light 9 from the semiconductor substrate 4 side. This irradiation with laser light 9 is performed by adjusting a focal point to an internal portion of the semiconductor substrate 4 by using laser light 9 having such a wavelength as to pass through the semiconductor substrate 4. Multi-photon absorption is thereby caused.

Scanning with laser light 9 is thereafter performed along the division guide line pattern 7. This scanning is performed so that the irradiation point is superposed on the division guide line pattern 7 in the direction of thickness of the semiconductor wafer 1. By this scanning with laser light 9, the modification region 10 is formed, as shown in FIG. 3C.

Thereafter, as shown in FIG. 3D, a cleavage 21 produced at a starting point corresponding to the modification region 10 is grown by applying an external force to the semiconductor wafer 1 by expansion for example. At this time, the cleavage 21 progresses toward the division guide line pattern 7 in the direction of thickness of the semiconductor wafer 1. This is made possible by utilizing a phenomenon of concentration of stress on a contact point between a plurality of elements.

As shown in FIG. 3E, the cleavage 21 that has reached the lamination progresses in the lamination along a side wall 22 of the division guide line pattern 7 to divide the semiconductor wafer 1.

At this time, there is a possibility of occurrence of interface separation 11 resulting from damage at the time of dividing if a low-k material such as SiOC or SiC is used for the interlayer insulating films 5, because the strength of adhesion between the interlayer insulating films 5 is low in such a case. However, the progress of interface separation 11 is limited by the division guide band pattern 8. Therefore the interface separation 11 does not extend beyond the division guide band pattern 8.

As described above, division of the semiconductor wafer 1 is performed along a cleavage surface formed by a cleavage produced from a starting point corresponding to the modification region 10, i.e., the side wall surface 22 of the division guide line pattern 7. Therefore, the working width (dicing lane) for division is not a physical recognizable width and the scribe lane 3 can be made narrower. Further, interface separation 11 can be limited by the division guide band pattern 8. Thus, the semiconductor wafer 1 can be divided while suppressing unnecessary chipping, interface separation and meandering.

According to a trial calculation made by the inventors of the present invention, the width of scribe lane 3 can be reduced to 15 to 30 μm, depending on the interlayer insulating film material and the structure used, if the division guide pattern 20 in this embodiment is used.

As described above, a cleavage point on the semiconductor wafer 1 is determined by the division guide line pattern 7 formed with high position accuracy in the semiconductor manufacturing process. Therefore, the semiconductor device obtained by dividing the semiconductor wafer 1 has, in its side surface, the modification region 10 formed in the semiconductor substrate 4 and the cleavage surface extending from the modification region 10 to the division guide pattern 20, and the side surface of the semiconductor device is formed as a division surface extending orderly along the division guide pattern 20. As a result, the semiconductor device manufactured in this manner has an extremely small amount of chipping, improved mechanical strength and high size accuracy in comparison with a semiconductor device having a surface formed by fracture working using the conventional dicing saw.

### Second Embodiment

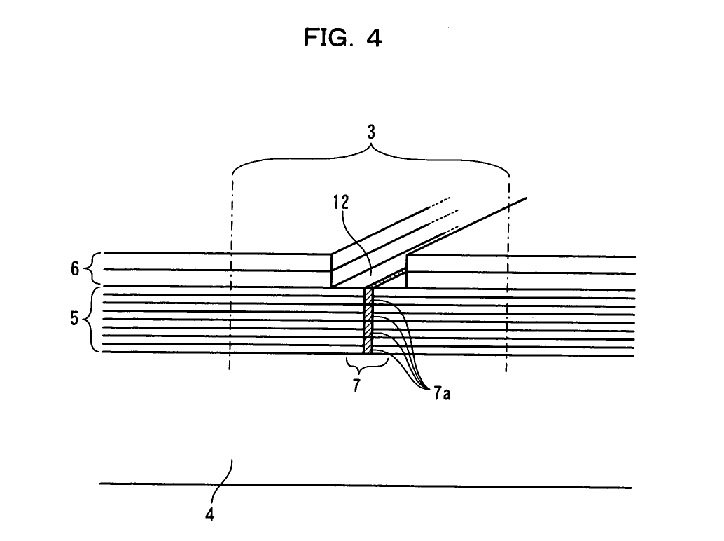

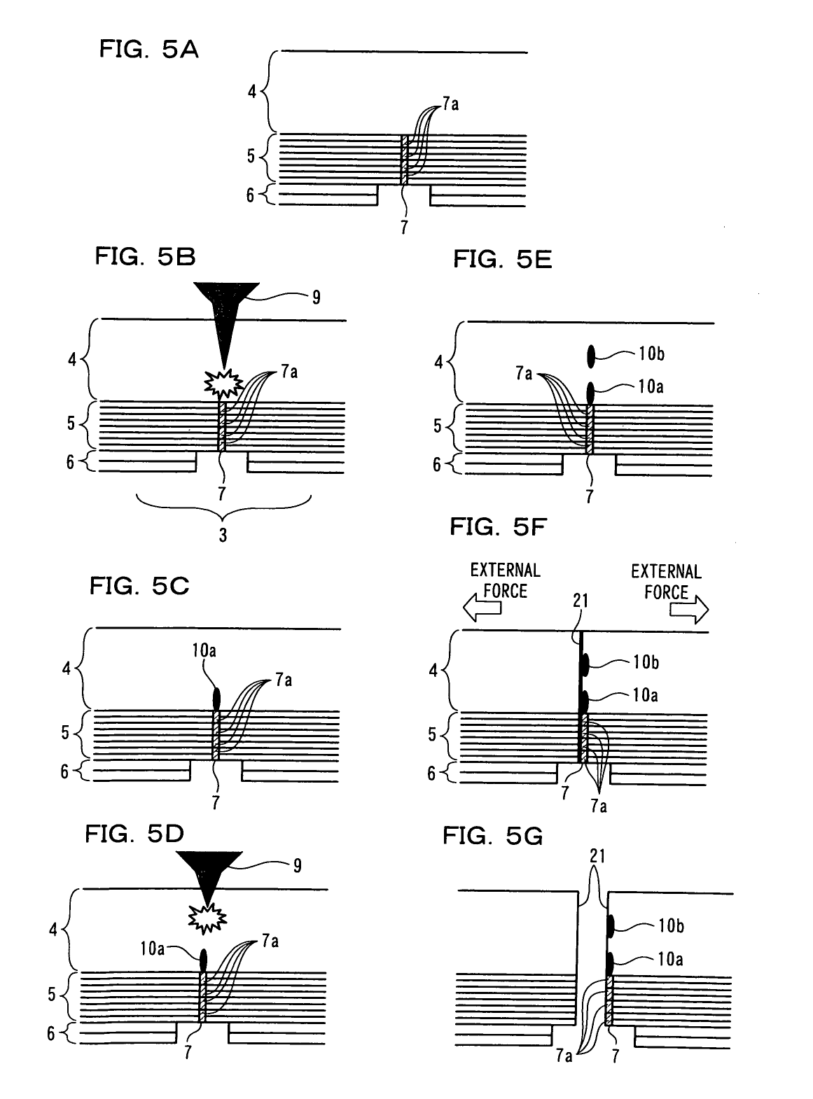

FIG. 4 shows a second embodiment of the present invention. FIG. 4 is a sectional view taken along line a-a′ in FIG. 1, and FIGS. 5A to 5G are schematic diagrams showing the method of manufacturing the semiconductor device by using the semiconductor wafer 1 shown in FIG. 4.

In FIGS. 1, 4, and 5A to 5G, reference numeral 12 denotes a slit provided in passivation films 6. Other members are the same as those shown in FIG. 1 and 2, and the description for them will not be repeated.

This embodiment differs from the first embodiment in that no division guide band patterns are provided in the division guide pattern 20. The division guide pattern 20 includes a division guide line pattern 7 and the slit 12 formed along the division guide line pattern 7. The division guide line pattern 7 has a stack structure in which only line vias 7a are stacked.

This structure is used, for example, in a case where the adhesion between interlayer insulating films 5 is high and there is substantially no risk of interlayer film separation. This structure is suitably used in the manufacturing method shown in FIGS. 5A to 5G.

In the manufacturing method shown in FIGS. 5A to 5G, the semiconductor wafer 1 is irradiated with laser light 9 from the semiconductor substrate 4 side as shown in FIG. 5B. This irradiation with laser light 9 is performed by adjusting a focal point to a location in contact with the division guide line pattern 7 by using laser light 9 having such a wavelength as to pass through the semiconductor substrate 4. Multi-photon absorption is thereby caused.

Scanning with laser light 9 is thereafter performed along the division guide line pattern 7. This scanning is performed so that the irradiation point is superposed on the division guide line pattern 7 in the direction of thickness of the semiconductor wafer 1. By this scanning with laser light 9, a modification region 10a is formed, as shown in FIG. 5C. Thereafter, as shown in FIG. 5D, scanning with laser light 9 is again performed along the division guide line pattern 7 by shifting the laser light 9 focal point, thereby forming a cleavage region 10b such as shown in FIG. 5E.

Thereafter, as shown in FIG. 5F, an external force is applied by expansion or the like to divide the semiconductor wafer 1 by means of a cleavage 21 produced from starting points corresponding to the modification regions 10a and 10b, thus forming the semiconductor device.

According to this method, the cleavage 21 produced from starting points corresponding to the modification regions 10a and 10b extend positively along the division guide line pattern 7. Therefore, the semiconductor device can be obtained with higher accuracy. Also, the semiconductor wafer 1 can be divided with high accuracy even if the thickness thereof is large. Further, in this embodiment, it is, of course, possible to form the division guide band patterns described above with respect to the first embodiment.

### Third Embodiment

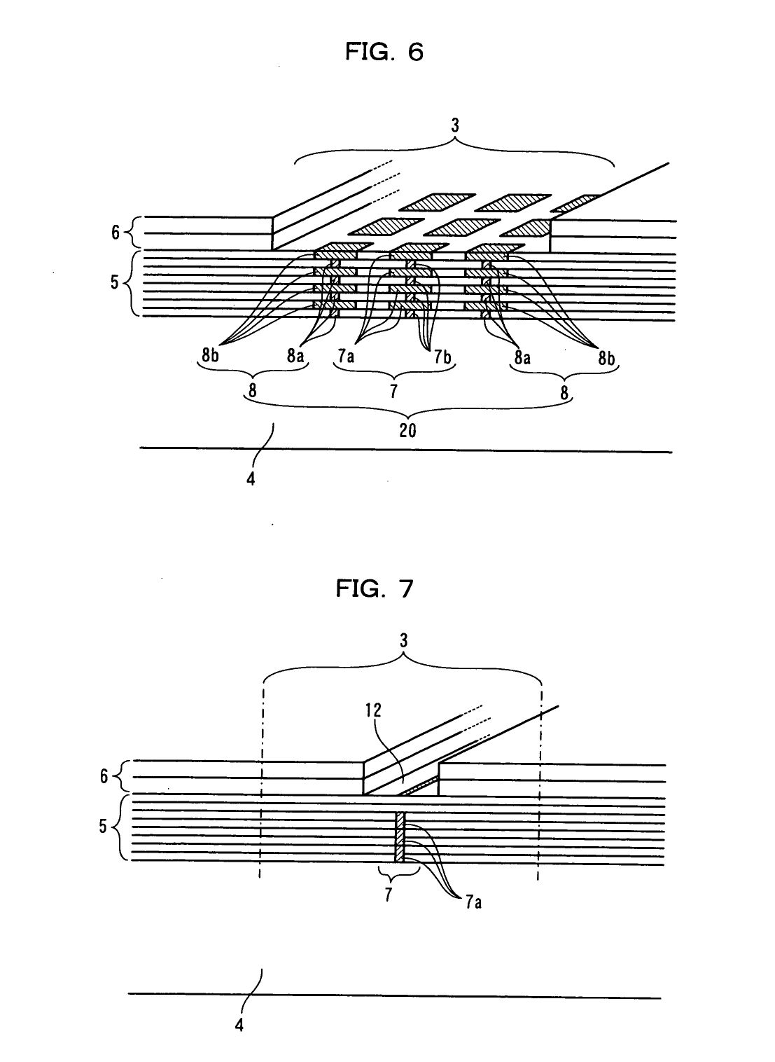

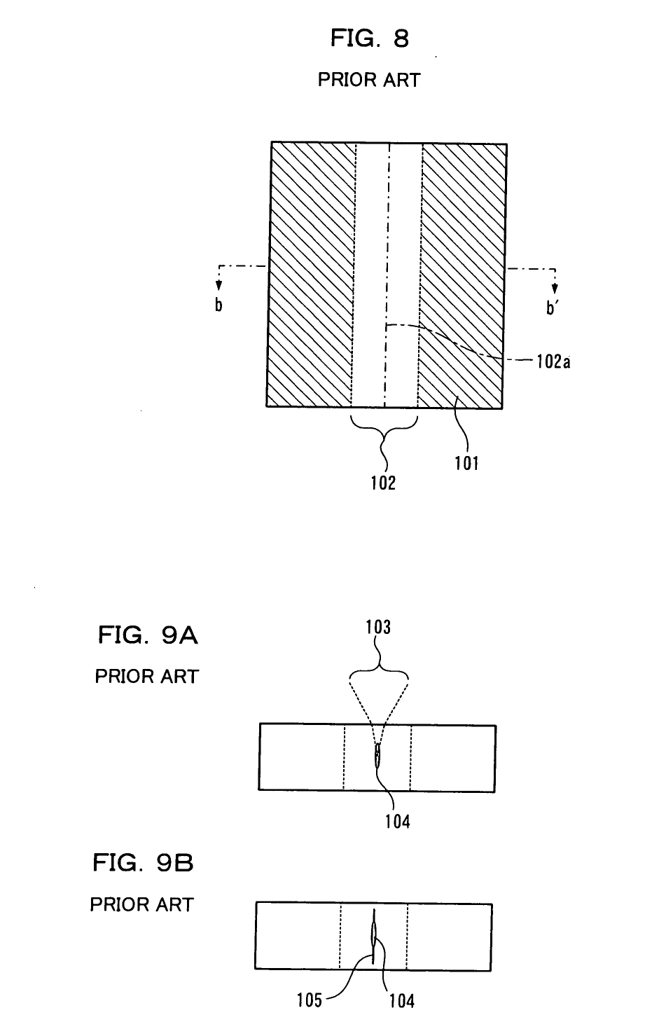

FIG. 6 shows a third embodiment of the present invention. FIG. 6 is a sectional view taken along line a-a′ in FIG. 1. Referring to FIG. 6, the third embodiment differs from the first embodiment in that only division guide band patterns 8 are provided to form a division guide pattern 20 without providing any division guide line pattern.

Dot pattern portions 8b are arranged in a grid array. However, it is not necessary to arrange the pattern portions in rows in all directions. For example, dot pattern portions 8b may be provided in a staggered arrangement. Also, a stack structure using only vias 8a or stack structure using dot pattern portions 8b without forming vias 8a may also suffice.

Further, while in this embodiment the division guide band patterns 8 are formed by groups of dot pattern portions 8b, an arrangement may alternatively be used in which a plurality of division guide line patterns 7 in the second embodiment may be located in parallel to each other.

### Fourth Embodiment

FIG. 7 shows a fourth embodiment of the present invention. FIG. 7 is a sectional view taken along line a-a′ in FIG. 1.

Referring to FIG. 7, the fourth embodiment differs from the second embodiment in that line vias 7a in a division guide line pattern 7 is formed only through a height lower than the uppermost layer in interlayer insulating films 5. This arrangement is effective particularly in a case where the vias are made of an easily corrodible material such as copper and it is undesirable to expose the vias in the surface of the semiconductor wafer 1. In the above-described embodiments, other devices or elements (not particularly shown in the drawings) such as a device separation structure called local oxidation of silicon (LOCOS) or shallow trench isolation (STI), gates and pieces of wiring formed of polysilicon may also be formed in the semiconductor substrate 4. Also, needless to say, the semiconductor substrate 4 may be a chemical compound semiconductor substrate such as a SiGe substrate or a GaAs substrate.

1-10. (canceled)

11. A method of manufacturing a semiconductor device, comprising:
forming a semiconductor wafer by forming a lamination on a semiconductor substrate; and
performing scanning with laser light, wherein
when the semiconductor wafer is formed, a plurality of semiconductor elements, division regions for separating the plurality of semiconductor elements into individual semiconductor devices and a division guide pattern formed at least in a portion of each division region are provided in the lamination, and
when scanning with laser light is performed, laser light is moved for scanning along the division guide pattern formed in each division region in the semiconductor wafer, a modification region is formed in the semiconductor substrate by irradiation with the laser light, and a cleavage produced from a starting point corresponding to the modification region is guided by the division guide pattern.

12. The method of manufacturing a semiconductor device according to claim 11, further comprising dividing the semiconductor wafer, wherein when the semiconductor wafer is divided, a mechanical stress is produced in the semiconductor wafer along the division guide pattern, the cleavage produced from a starting point corresponding to the modification region is guided by the division guide pattern, and the semiconductor wafer is divided along the division guide patterns to be separated into the individual semiconductor devices.

13. The method of manufacturing a semiconductor device according to claim 11, wherein when scanning with the laser light is performed, the laser light is radiated while adjusting a focal point to an internal portion of the semiconductor substrate to form the modification region in the semiconductor substrate by multi-photon absorption.

14. The method of manufacturing a semiconductor device according to claim 13, wherein scanning with the laser light is performed a certain number of times by changing the focal point.

15. The method of manufacturing a semiconductor device according to claim 13, wherein when scanning with the laser light is performed, the modification region is formed adjacent to the division guide pattern.

16. (canceled)
